(19) United States
(12) Patent Application Publication
(10) Pub. No.: US 2025/0366141 A1
(43) Pub. Date: Nov. 27, 2025

(54) MANAGING TOP SELECT GATES IN SEMICONDUCTOR DEVICES

(71) Applicant: Yangtze Memory Technologies Co., Ltd., Wuhan (CN)

(72) Inventors: Shuangshuang WU, Wuhan (CN); Huiqi LIAO, Wuhan (CN); Di WANG, Wuhan (CN); Kun ZHANG, Wuhan (CN)

(21) Appl. No.: 18/790,917

(22) Filed: Jul. 31, 2024

Related U.S. Application Data
(63) Continuation of application No. PCT/CN2024/095161, filed on May 24, 2024.

(51) Int. Cl. H01L 29/423; H01L 27/088

(52) U.S. Cl. CPC H10D 64/512; H10D 84/83

(57) ABSTRACT

Systems, devices, and methods for managing top select gates in a semiconductor device are provided. In one aspect, a semiconductor device includes a first stack of conductive layers and isolating layers alternating with each other, and a second stack of dielectric layers and isolating layers alternating with each other. The second stack is connected to the first stack. A first portion of the first stack includes: one or more top select gate (TSG) layers of the conductive layers in a first part, and one or more conductive layers of the conductive layers in a second part. The first part includes a first staircase structure having one or more first stairs corresponding to the one or more TSG layers. The second part includes a second staircase structure having one or more second stairs. The first staircase structure and the second staircase structure are separated by a separation structure.

### CROSS-REFERENCE TO RELATED APPLICATIONS

This application is a continuation of International Application No. PCT/CN2024/095161, filed on May 24, 2024, the disclosure of which is hereby incorporated by reference in its entirety.

### TECHNICAL FIELD

The present disclosure relates to semiconductor devices and fabrication processes for semiconductor devices.

### BACKGROUND

Semiconductor memory devices may be classified into non-volatile memory devices, such as flash memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for managing top select gates (TSG) in three-dimensional (3D) semiconductor devices.

One aspect of the present disclosure features a semiconductor device, including a first stack of conductive layers and isolating layers alternating with each other along a first direction, and a second stack of dielectric layers and isolating layers alternating with each other along the first direction. The second stack is connected to the first stack along a second direction perpendicular to the first direction. A first portion of the first stack includes: one or more top select gate (TSG) layers of the conductive layers in a first part of the first portion of the first stack, and one or more conductive layers of the conductive layers corresponding to the one or more TSG layers in a second part of the first portion of the first stack. The second part of the first portion of the first stack is connected to the second stack. The first part includes a first staircase structure having one or more first stairs corresponding to the one or more TSG layers. The second part includes a second staircase structure having one or more second stairs corresponding to the one or more conductive layers. The first staircase structure and the second staircase structure are separated by a separation structure between the first part and the second part.

In some implementations, a number of the one or more first stairs is equal to a number of the one or more second stairs.

In some implementations, the semiconductor device includes a TSG cut structure extending through the first part of the first portion of the first stack and at least one of the conductive layers in a second portion of the first stack that is adjacent to the first portion of the first stack along the first direction. The TSG cut structure is configured to separate the one or more TSG layers into a plurality of TSG electrodes.

In some implementations, a conductive layer of the at least one of the conductive layers includes a first section and a second section. The TSG cut structure is configured to separate the first section of the conductive layer into a plurality of layer portions, and the second section of the conductive layer connects ends of the plurality of layer portions.

In some implementations, the second section of the conductive layer is between the TSG cut structure and the second stack along the second direction.

In some implementations, the TSG cut structure includes a first end and a second end opposite to the first end along the second direction. The second end of the TSG cut structure is between the first staircase structure and the second stack.

In some implementations, the second end of the TSG cut structure is between the first staircase structure and the second staircase structure.

In some implementations, the semiconductor device includes TSG contact structures. One of the TSG contact structures is in contact with a corresponding one of the plurality of TSG electrodes at a corresponding one of the one or more first stairs along the first direction.

In some implementations, a slit structure extending along the second direction and includes a first portion and a second portion. The first portion and the second portion of the slit structure are separated by a slit cut.

In some implementations, the slit cut is between the first part of the first portion of the first stack and the second stack along the second direction.

In some implementations, the semiconductor device further includes a plurality of contact structures. The plurality of contact structures extends into the second stack at different depths, and where one of the plurality of contact structures includes a vertical contact and an interconnect structure connected with the vertical contact.

In some implementations, the interconnect structure is connected with a corresponding one of the at least one of the conductive layers.

Another aspect of the present disclosure features a method including: forming a first stack of conductive layers and isolating layers alternating with each other along a first direction; and forming a second stack of dielectric layers and isolating layers alternating with each other along the first direction. The second stack is connected to the first stack along a second direction perpendicular to the first direction. A first portion of the first stack includes: one or more top select gate (TSG) layers of the conductive layers in a first part of the first portion of the first stack, and one or more conductive layers of the conductive layers corresponding to the one or more TSG layers in a second part of the first portion of the first stack, the second part of the first portion of the first stack being connected to the second stack. The first part includes a first staircase structure having one or more first stairs corresponding to the one or more TSG layers, and the second part includes a second staircase structure having one or more second stairs corresponding to the one or more conductive layers. The first staircase structure and the second staircase structure are separated by a separation structure between the first part and the second part.

In some implementations, the method includes forming a stack structure of the dielectric layers and the isolating layers alternating with each other along the first direction; and etching a first portion of the stack structure to form a first initial staircase in a first part of the first portion and a second initial staircase in a second part of the first portion.

In some implementations, the method includes partially replacing the dielectric layers with the conductive layers in the stack structure to form the first stack.

In some implementations, partially replacing the dielectric layers includes: replacing the dielectric layers with the TSG layers in the first initial staircase to form the first staircase structure and with the one or more conductive layers in the second initial staircase to form the second staircase structure.

In some implementations, the method includes forming a TSG cut structure extending through the TSG layers and at least one of the conductive layers along the first direction. The TSG cut structure is configured to separate the TSG layers into a plurality of TSG electrodes.

In some implementations, the TSG cut structure includes a first end and a second end opposite to the first end along the second direction. The second end of the TSG cut structure is between the first staircase structure and the second staircase structure.

In some implementations, the method includes forming a slit structure extending along the second direction; and forming a slit cut extending through the slit structure along the first direction. The slit cut separates the slit structure into a first segment and a second segment, and the slit cut is between the first staircase structure and the second stack.

In some implementations, the method includes forming a plurality of TSG contact structures, one of the TSG contact structures being in contact with a corresponding one of the TSG electrodes at a corresponding one of the one or more first stairs.

In some implementations, the method includes forming contact structures extending into the second stack at different depths, one of the contact structures being coupled to a corresponding one of the conductive layers.

Another aspect of the present disclosure features a semiconductor device including: a first stack of conductive layers and isolating layers alternating with each other along a first direction. A first portion of the first stack includes one or more top select gate (TSG) layers of the conductive layers; a second stack of dielectric layers and isolating layers alternating with each other along the first direction. The second stack is connected to the first stack along a second direction perpendicular to the first direction; and a TSG cut structure extending through the first portion of the first stack and at least one of the conductive layers in a second portion of the first stack that is adjacent to the first portion of the first stack along the first direction, the TSG cut structure being configured to separate the one or more TSG layers into a plurality of TSG electrodes. A conductive layer of the at least one of the conductive layers includes a first part and a second part, and the second part is between the first part and the second stack. The TSG cut structure is configured to separate the first part of the conductive layer into a plurality of layer portions, and the second part connects ends of the plurality of layer portions.

In some implementations, the first portion includes a first staircase structure having one or more first stairs corresponding to the one or more TSG layers. The semiconductor device further includes TSG contact structures, one of the TSG contact structures being in contact with a corresponding one of the plurality of TSG electrodes at a corresponding one of the first stairs.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a top view of an example semiconductor device.

FIG. 2A illustrates a cross-section view of an example semiconductor device.

FIG. 2B illustrates a top view of example first staircases and second staircases.

FIG. 2C illustrates a cross-section view of an example semiconductor device that passes through a SG cut.

FIG. 3A illustrates a top view of a sliced gate layer in an example semiconductor device.

FIG. 3B illustrates a 3D view of a part of an example semiconductor device.

FIGS. 4A-4D illustrates cross-section views of the example semiconductor device of FIG. 2A at various stages of a manufacturing process.

FIG. 5 illustrates a flow chart of an example process for forming an example semiconductor device.

FIG. 6 illustrates a block diagram of a system.

It is to be understood that the various exemplary implementations shown in the figures are merely illustrative representations and are not necessarily drawn to scale.

### DETAILED DESCRIPTION

In some 3D memory devices, such as 3D NAND memory devices, a stack of gate electrodes may be arranged over a substrate, with a plurality of semiconductor channels through and intersecting word lines, into the implanted substrate. The bottom select gates (BSG) function as source select gate. The top select gates (TSG) function as drain select gate. The gate layers between the TSG and the BSG function as word lines (WL). The intersection of a word line and a semiconductor channel forms a memory cell. The memory devices can have TSG cut structures which extend through the TSG layers along a vertical direction perpendicular to the substrate surface. In some situations, due to process limitations, at least one gate layer adjacent to the TSG layers can also be inevitably cut. The gate layers that are cut by the TSG cut structures may not be functional, as the TSG cut structures divide them into isolated sections. Such non-functional gate layers can reduce storage capacity of the memory devices.

Implementations of the present disclosure provide semiconductor devices and methods for form such semiconductor devices. In some implementations, a semiconductor device includes a first stack of conductive layers and isolating layers alternating with each other along a first direction, and a second stack of dielectric layers and isolating layers alternating with each other along the first direction. The second stack is connected to the first stack along a second direction perpendicular to the first direction. A first portion of the first stack includes: one or more top select gate (TSG) layers of the conductive layers in a first part of the first portion of the first stack, and one or more conductive layers of the conductive layers corresponding to the one or more TSG layers in a second part of the first portion of the first stack. The second part of the first portion of the first stack is connected to the second stack. The first part includes a first staircase structure having one or more first stairs corresponding to the one or more TSG layers. The second part includes a second staircase structure having one or more second stairs corresponding to the one or more conductive layers. The first staircase structure and the second staircase structure are separated by a separation structure between the first part and the second part.

Implementations of the present disclosure can provide one or more of the following technical advantages and/or benefits. For example, TSG layers can be formed together with gate layers by replacing dielectric layers (also called sacrificial layers in some cases) with a conductive material, which reduce the requirement for additional deposition steps to form TSG layers. A bowl-shaped staircase structure can be formed by extending through multiple TSG layers, providing a landing area for TSG contacts to pad out TSGs. Furthermore, TSG cut structures can have a length shorter than that of gate layers along a horizontal direction parallel to a substrate surface. Therefore, even if TSG cut structure extends through a gate layer that is adjacent to the TSG layers, the TSG cut structure does not completely separate the gate layer into isolated segments because of its shorter length compared to the gate layer. Therefore, the gate layer that is cut by the TSG cut structure can still be functional like a continuous layer, thereby increasing the storage capacity of the memory device.

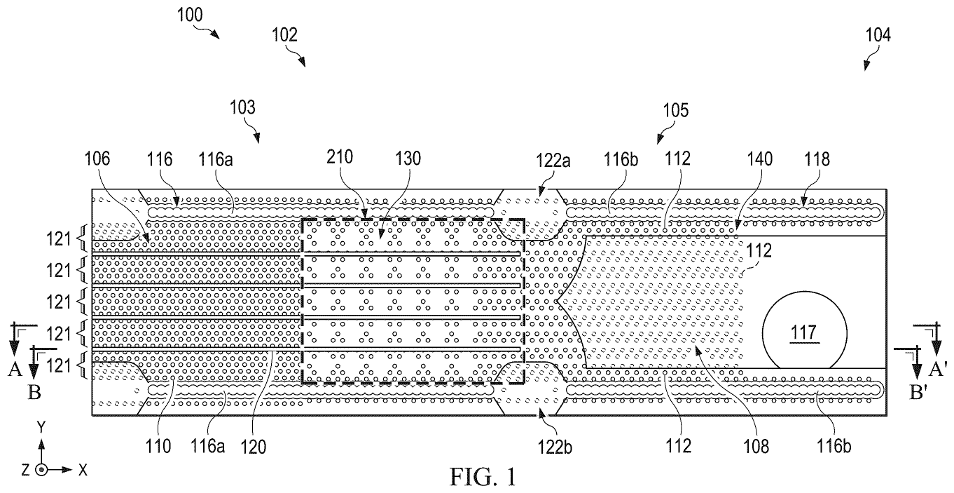

FIG. 1 illustrates a top view of an example semiconductor device 100. In some implementations, the semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1, the semiconductor device 100 includes an array region 102 and a connection region 104 adjacent to the array region 102 along a first horizontal direction (e.g., the X direction). It is understood that the example in FIG. 1 is for illustration purpose and is not intended to be construed in a limiting sense. In practice, any suitable arrangement of various regions in the semiconductor device 100 can be applied. In some instances, the semiconductor device 100 can have two connection regions 104 and an array region 102 arranged between the two connection regions 104 along the X direction. In some other instances, the semiconductor device 100 can have two array regions 102 and a connection region 104 between the two array regions 102 along the X direction.

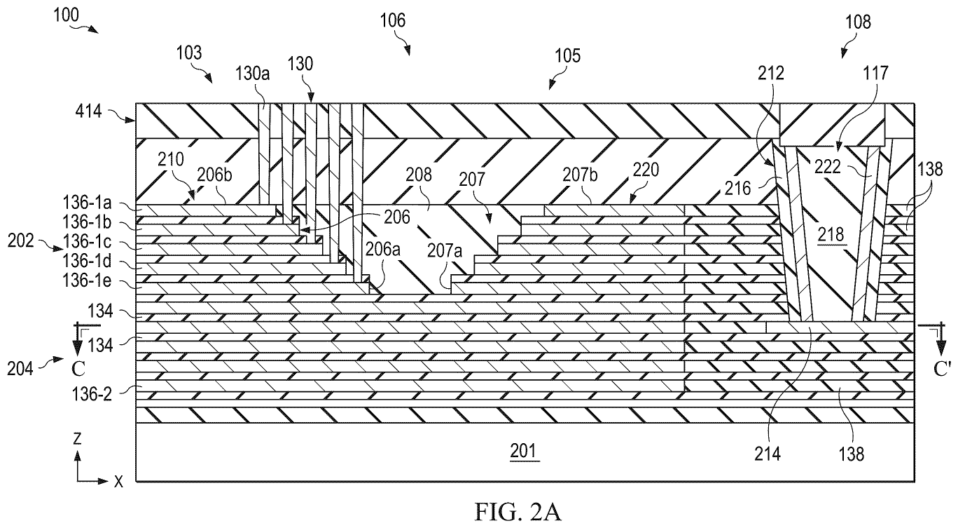

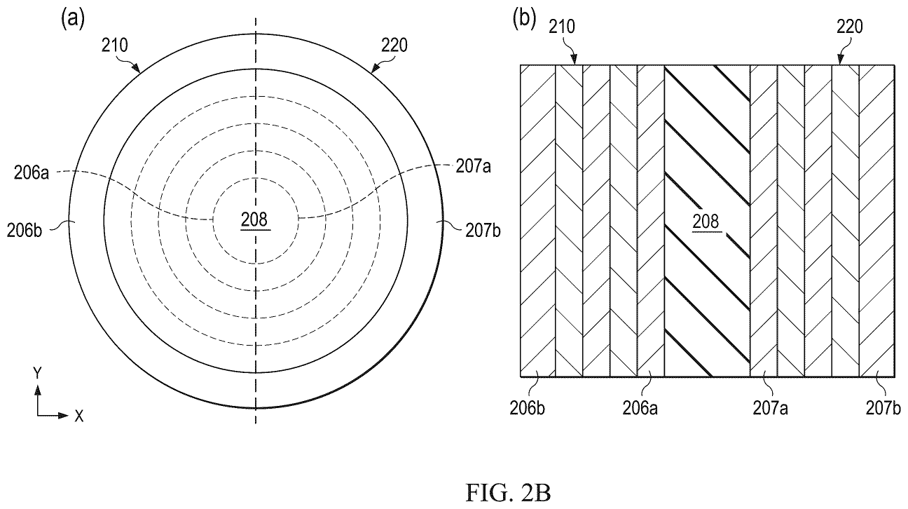

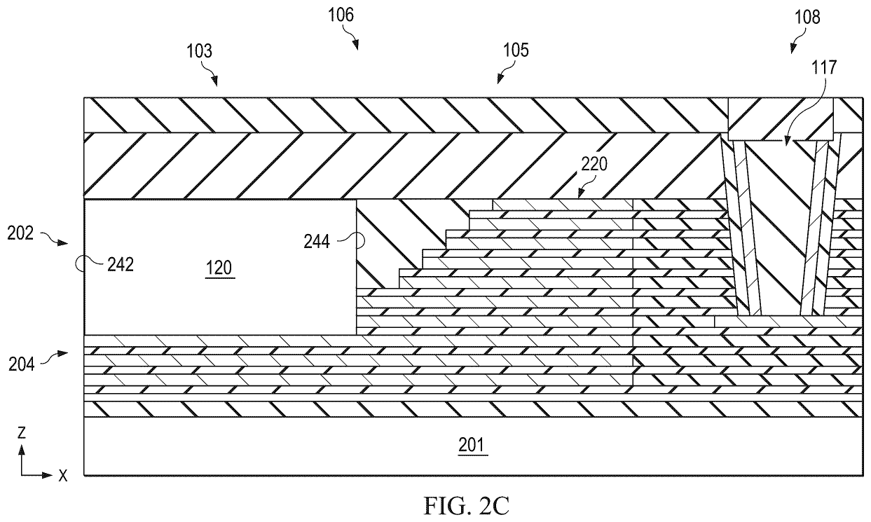

The semiconductor device 100 includes a first stack 106 of alternating conductive layers and isolating layers (e.g., conductive layers 136 and isolating layers 134 as shown in FIG. 2A). At least one upper layer of the conductive layers 136 can be employed as top select gate (TSG) layers. The remaining conductive layers can be employed as gate layers for the memory cells. In some implementations, a part of the first stack 106 can be in the array region 102, and another part of the first stack 106 can be in the connection region 104. The part of the first stack 106 that is in the connection region 104 can also be referred to as the side connection stack 140 in this disclosure. The semiconductor device 100 further includes a second stack 108 of alternating dielectric layers and isolating layers (e.g., dielectric layers 138 and isolating layers 134 as shown in FIG. 2A). In some implementations, the second stack 108 can be in the connection region 104. The first stack 106 can be connected to the second stack 108. The second stack 108 can be between two side connection stacks 140 along Y axis, e.g., bit line direction.

The semiconductor device 100 can include an array of channel structures 110 extending through the first stack 106. In some implementations, the array of channel structures 110 is in the array region 102. Each channel structure 110 can be used to form a string of memory cells coupled in serial along a vertical direction (e.g., Z direction) perpendicular to the first horizontal direction. In some implementations, the semiconductor device 100 can include dummy channel structures 112 (also referred to as dummy memory strings) for process variation control during fabrication and/or for additional mechanical support. The dummy channel structures 112 can extend through the first stack 106 and/or the second stack 108. In some implementations, the dummy channel structures 112 are in the connection region 104. For example, some dummy channel structures 112 can be in the second stack 108 and/or the side connection stack 140. In some implementations, the dummy channel structures 112 are in the array region 102 (e.g., an area adjacent to the connection region 104). In some implementations, the dummy channel structures 112 have structures identical or substantially similar to that of the channel structures 110.

The semiconductor device 100 can include contact structures 117 for padding out gate layers 136 in the first stack 106. In some implementations, the contact structures 117 are in the connection region 104. A contact structure 117 can be configured to connect one or more corresponding conductive layers of the conductive layers of the first stack 106 (e.g., gate layers 136) to the control circuities.

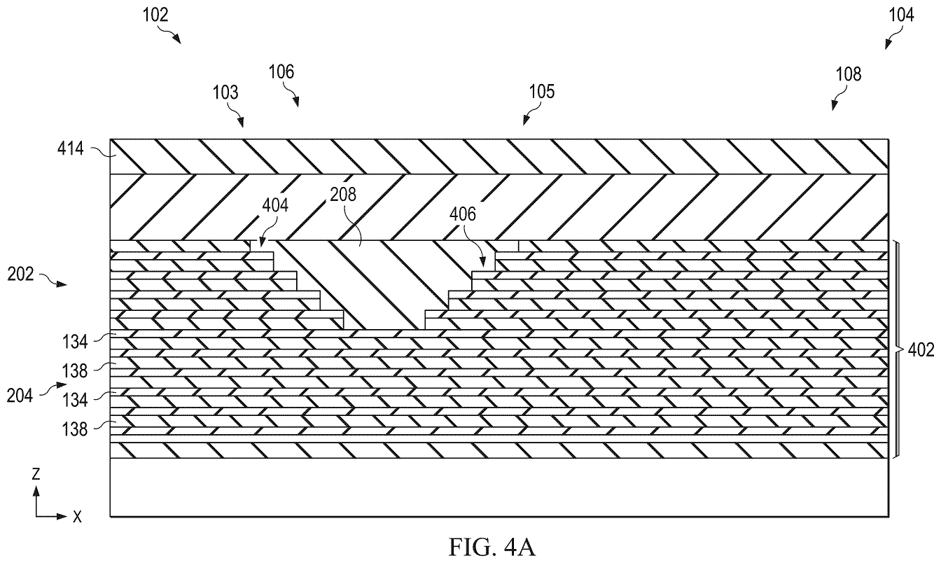

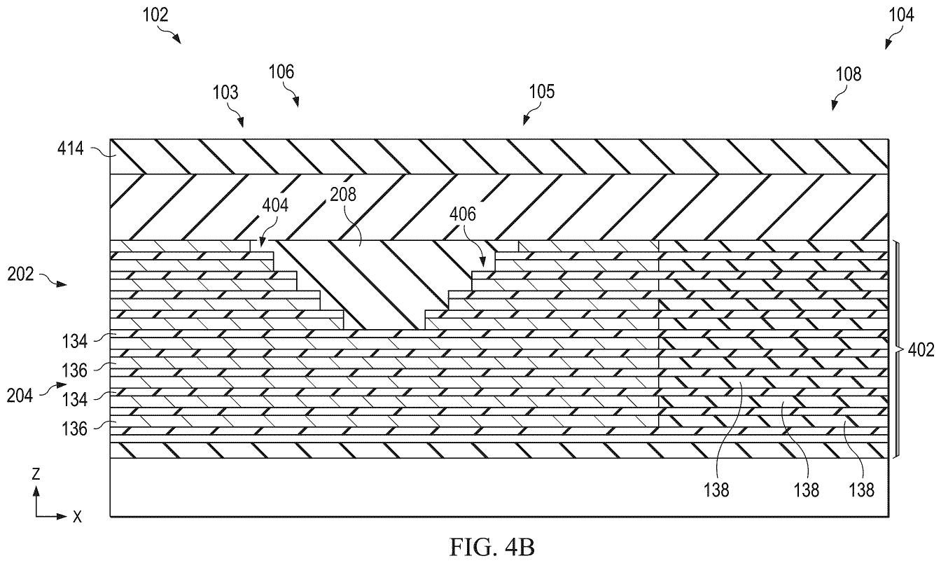

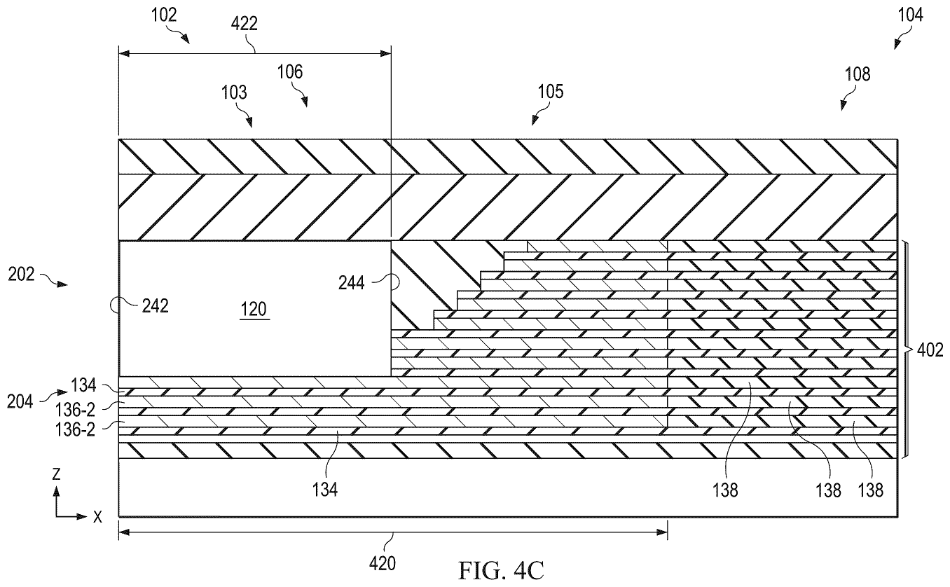

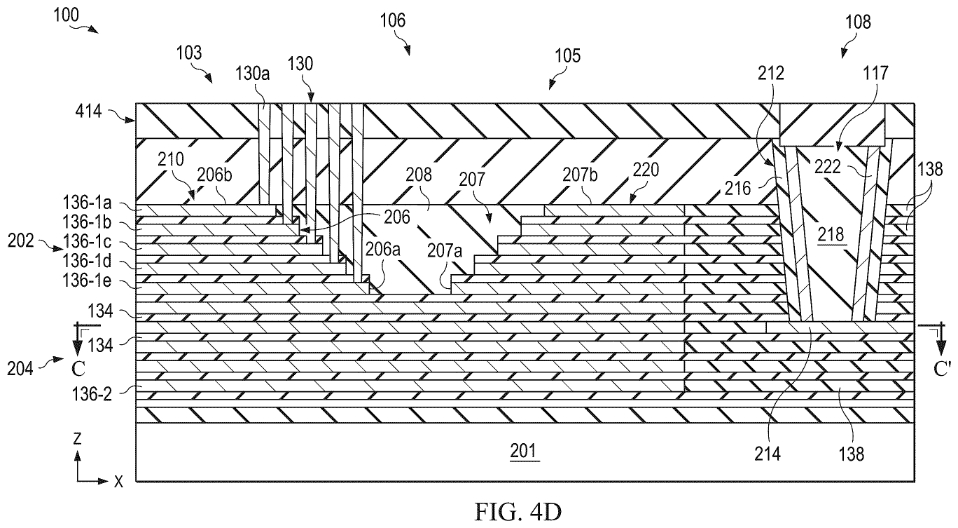

The semiconductor device 100 can further include one or more slit structures 118. Each slit structure 118 can extend in the X direction. The slit structure 118 can extend into both the array region 102 and the connection region 104. In some implementations, the slit structures 118 can divide an array region into multiple memory blocks, and a memory block is between two adjacent slit structures 118. In some implementations, the slit structure 118 can function as a common source contact for the channel structures 110 in the array region 102. In some implementations, each slit structure 118 can include multiple segments 116a, 116b (referred to generally as segments 116 and individually as segment 116). In some implementations, the segments 116 can be separated and spaced by slit cuts 122a, 122b (referred to generally as slit cuts 122 and individually as slit cut 122), along the X direction. For example, a slit cut 122a separates the slit structure 118 into a first segment 116a in the array region 102 and a second segment 116b in the connection region 104, as illustrated in FIG. 1. Different segments can be used for two-step tungsten (W) replacement during the manufacturing process, as described below in reference to FIG. 4B. The slit cuts 122 can reduce stress built in the slit structure 118 during the manufacturing process, thereby preventing the slit structure 118 from bending or cracking. In some implementations, as shown in FIG. 1, the slit cut 122 is in the connection region 104 and is adjacent to the array region 102. In some other implementations, the slit cut 122 is in the array region 102 and is adjacent to the connection region 104. In some other implementations, the slit cut 122 can have a portion in the array region 102 and another portion in the connection region 104. In some implementations (not shown in FIG. 1), the slit structure 118 can further include one or more segments extending along a second horizontal direction (e.g., the Y direction). In some implementations, the slit structure 118 can include multiple segments connected in an H shape or a T shape. In some implementations, the segments 116 of each slit structure 118 can have similar or a same width (e.g., along the Y direction). In some other implementations, the segments 116 of each slit structure 118 can have different widths (e.g., along the Y direction). In some implementations, along the Y direction, a width of the segment 116 in the connection region 104 is larger than a width of the segment 116 in the array region 102. For example, the width of the segment 116 in the connection region 104 can be approximately 1.5 to 2 times that of the segment 116 in the array region 102.

In some implementations, slit structure 118 is an insulating structure that does not include any contact therein (i.e., not functioning as the source contact) and thus, does not introduce parasitic capacitance and leakage current with conductive layers 136. In some implementations, slit structure 118 includes polysilicon. In some implementations, slit structure 118 is a front-side source contact further including an inner conductive portion (e.g., including W, polysilicon, and/or TiN) circumscribed by slit spacer. In some implementations, the slit cut 122 is made of dielectric materials including, but not limited to, silicon oxide, silicon nitride, silicon oxynitride, low-k dielectrics, or any combination thereof.

The first stack 106 can include a first part 103 and a second part 105. The second part 105 of the first stack 106 is arranged between the first part 103 of the first stack 106 and the second stack 108 along X direction. The first part 103 can include one or more top select gate (TSG) layers of the conductive layers. In some implementations, the first part 103 of the first stack 106 has a first staircase structure 210 (e.g., in the region enclosed by dashed lines in FIG. 1) for padding out TSG layers. In some implementations, the second part 105 has a second staircase structure 220. In some implementations, the first staircase structure 210 and the second staircase structure 220 together form a bowl shape staircase, as illustrated in FIGS. 2A and 2B.

The semiconductor device 100 can include at least one TSG cut structure 120. Each TSG cut structure 120 can extend through the first stack 106 along the x-direction. The TSG cut structures 120 can be configured to separate the TSG layers (e.g., at least one upper layer of the conductive layers 136) into multiple TSG electrodes 121. Each TSG electrode 121 can extend in the array region 102 along the x-direction, as illustrated in FIG. 1. Each TSG electrode 121 can control corresponding memory strings. A gate-selective voltage can be applied on the TSG electrode for selecting the respective strings in operations. TSG cut structure 120 can be used for electrically insulating the TSG electrodes 121 between two adjacent groups of memory strings. In some implementations, the TSG cut structures 120 only partially extend through the first stack 106 along X direction such that the TSG cut structures 120 are not in contact with the second stack 108, as illustrated in FIG. 1. In other words, the length of the TSG cut structures 120 along the X direction can be smaller than that of the gate layers 136. In some implementations, the TSG cut structures 120 do not extend into the second part 105 of the first stack 106, and thus it only cuts the first staircase structure 210 while leaving the second staircase structure 220 intact, e.g., as illustrated in FIG. 2C. In some implementations, TSG cut structures 120 are formed by a dielectric material, including, but not limited to, silicon oxide, silicon nitride, silicon oxynitride, or any combination thereof.

The semiconductor device 100 can include at least one TSG contact structure 130. Each TSG contact structure 130 can be in contact with a respective TSG electrode 121 of at a respective stair in the first staircase structure 210. The TSG contact structures 130 can pad out the TSG electrodes 121 to connect the TSGs with control circuitries.

FIG. 2A is a cross-section view of the semiconductor device 100 through an axis similar to the axis A-A′ of FIG. 1. It is to be understood that for ease of illustration, the channel structures 110 are not depicted in FIG. 2A. As shown, the 3D memory device 100 can include a substrate 201, which can include a doped semiconductor layer and can include silicon (e.g., single crystalline silicon), silicon germanium (SiGe), gallium arsenide (GaAs), germanium (Ge), silicon on insulator (SOI), germanium on insulator (GOI), or any other suitable materials. In some implementations, substrate 201 is a thinned substrate (e.g., a semiconductor layer), which was thinned by grinding, etching, chemical mechanical polishing (CMP), or any combination thereof. Substrate 201 of 3D memory device 100 includes two surfaces (e.g., a top surface and a bottom surface) extending laterally in the x-direction (e.g., the lateral direction). As used herein, whether one component (e.g., a layer or a device) is “on,” “above,” or “below” another component (e.g., a layer or a device) of a 3D memory device (e.g., 3D memory device 100) is determined relative to the substrate of the 3D memory device (e.g., substrate 201) in the z-direction (e.g., the vertical direction) when the substrate is positioned in the lowest plane of the 3D memory device in the z-direction.

In some implementations, 3D memory device 100 is a NAND Flash memory device in which memory cells are provided in the form of an array of NAND memory strings each extending vertically above substrate 201.

As shown in FIG. 1, the 3D memory device 100 can include two stacks, e.g., the first stack 106 and the second stack 108. As noted above, the first stack 106 has alternating conductive layers 136 and isolating layers 134. In some implementations, each conductive layer 136 in first stack 106 (e.g., a memory stack) functions as a gate conductor of memory cells in the NAND memory string. Conductive layers 136 can extend laterally coupling a plurality of memory cells. The conductive layers 136 can include conductive materials including, but not limited to, tungsten (W), cobalt (Co), copper (Cu), aluminum (Al), polysilicon, doped silicon, silicides, or any combination thereof. The isolating layers 134 can include dielectric materials including, but not limited to, silicon oxide, silicon nitride, silicon oxynitride, or any combination thereof.

The first stack 106 has two portions, e.g., a first portion 202 and a second portion 204, arranged along a vertical direction perpendicular to the substrate 201 (e.g., Z direction). The second portion 204 can be between the first portion 202 and the substrate 201. The second portion 204 of the first stack 106 can include the memory strings, while the first portion 202 of the first stack 106 can include TSGs for the corresponding memory strings. The conductive layers in the first portion 202 can be referred to as the TSG layers 136-1 (e.g., 136-1a, 136-1b, 136-1c, 136-1d, 136-1e) (referred to generally as TSG layers 136-1 and individually as TSG layer 136-1) in this disclosure, while the conductive layers in the second portion 204 can be referred as gate layers 136-2 in this disclosure.

The first portion 202 can include two parts, e.g., the first part 103 and the second part 105, arranged laterally along a direction parallel to the substrate 201 (e.g., X direction). The second part 105 can be between the first part 103 and the second stack 108. The first part 103 of the first portion 202 includes one or more TSG layers 136-1. As noted above, the TSG layers 136-1 can be the top layers of the conductive layers 136. Five TSG layers are illustrated in FIG. 2A, e.g., TSG layers 136-1a, 136-1b, 136-1c, 136-1d, and 136-1e. The TSG layers 136-1 can select specific memory cells or memory strings for read, program or erase operations within a NAND flash memory array under control of peripheral circuitries.

The first part 103 of the first portion 202 of the first stack 106 also includes the first staircase structure 210. The first staircase structure 210 has one or more first stairs 206 corresponding to the one or more TSG layers 136-1. For example, the number of first stairs 206 is equal to the number of TSG layers 136-1, and each TSG layer 136-1 is associated with one first stair 206. In some implementations, the first staircase structure 210 is descending toward the second part 105 along X direction. For example, the lowest stair 206a (e.g., the first stair 206 that is the closest to the substrate 201) is nearer to the second part 105 than the highest stair 206b.

The TSG layers 136-1 can be coupled to the peripheral circuitries through TSG contact structures 130. In some implementations, the TSG contact structures 130 are in contact with corresponding TSG electrodes 121 at corresponding first stairs 206. For example, as illustrated in FIGS. 1 and 2A, a first TSG contact structure 130a can be in contact with the corresponding TSG electrode 121 of the first TSG layer 136-1a. Different TSG contact structures 130 can extend vertically at different depths along the Z direction to land on the TSG electrodes 121 of the corresponding stairs. In some implementations, the TSG contact structures 130 include, but not limited to, W, Co, Cu, Al, TiN, TaN, polysilicon, or any combination thereof.

As illustrated in FIG. 2A, the second part 105 of the first stack 106 includes a second staircase structure 220. The second staircase structure 220 has one or more second stairs 207 corresponding to the one or more conductive layers 136. The second stairs 207 can be ascending towards the second stack 108 structure along X direction. The first staircase structure 210 and the second staircase structure 220 can be separated by a separation structure 208 between the first part 103 and the second part 105. The separation structure 208 can be made of dielectric materials. In some implementations, a number of the first stairs 206 is equal to a number of the second stairs 207. The first staircase structure 210 and the second staircase structure 220 can be symmetric about the separation structure 208, as illustrated in FIG. 2A.

The first staircase structure 210 and the second staircase structure 220 can have various shapes in a top view. FIG. 2B illustrates top views of example first staircase structure 210 and second staircase structure 220. Diagram (a) of FIG. 2B illustrates a concentric staircase structure with a circular shape. Diagram (b) of FIG. 2B illustrates a non-concentric staircase structure with a square or rectangular shape. The center stairs, e.g., the lowest stair 206a, 207a, can be the bottommost stair closest to the substrate 201 of the semiconductor device 100. Conversely, the outer edge stair, e.g., the highest stair 206b, 207b, can be the topmost stair farthest from the substrate 201 of the semiconductor device 100. It is to be understood that other suitable shapes of the staircase structure can also be deployed.

Referring back to FIG. 2A, the semiconductor device 100 includes the second stack 108. As noted above, the second stack 108 can include alternating isolating layers 134 and dielectric layers 138. The dielectric layers 138 can be corresponding to the conductive layers of the first stack 106.

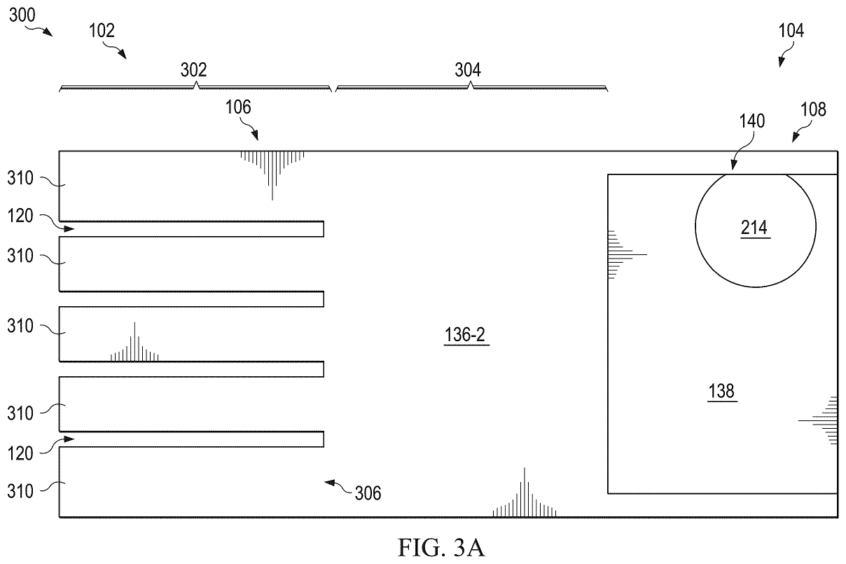

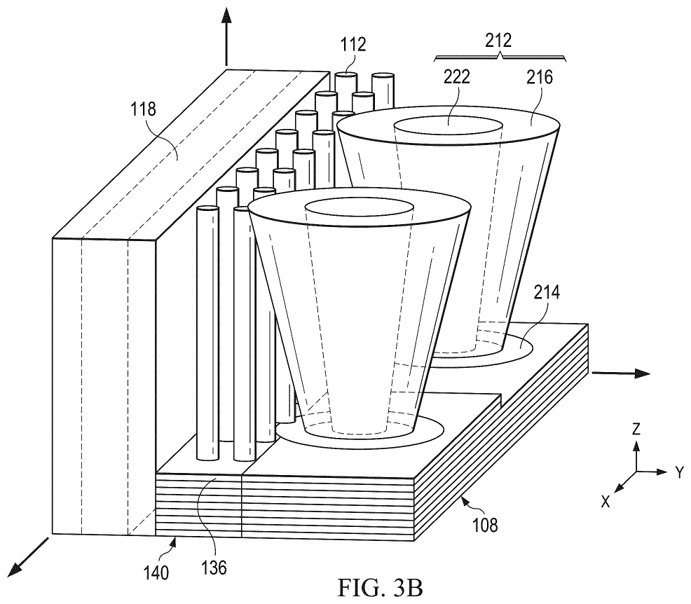

The semiconductor device 100 can further include contact structures 117 which extend vertically through the second stack 108 at different depths along the Z direction and land at corresponding dielectric layers 138. A contact structure 117 can include a vertical contact 212 and an interconnect structure 214 connected to the vertical contact 212. The vertical contact 212 can extend vertically through one or more dielectric layers 138 and be in contact with the interconnect structure 214 at its bottom. In some implementations, as shown in FIG. 2A, the vertical contact 212 includes a conductive layer 222 surrounded by a spacer layer 216. The spacer layer 216 can isolate the conductive material of the vertical contact 212 from surrounding material of the second stack 108. In some implementations, the vertical contact 212 includes a dielectric body structure 218 which is surrounded by the conductive layer 222, as illustrated in FIG. 2A. In some implementations, the vertical contact 212 is a solid conductive structure (e.g., metal), without a dielectric body structure 218, e.g., as illustrated in FIG. 3B.

The interconnect structure 214 can be formed by replacing a portion of the corresponding dielectric layer with a conductive material, as illustrated in FIGS. 2A and 3B. In some implementations, an area of the interconnect structure 214 is larger than an area of the vertical contact in a cross-sectional plane parallel to the substrate surface (e.g., X-Y plane). In some implementations, the interconnect structure 214 is in contact with a corresponding conductive layer 136 in the side connection stack 140 located in the connection region 104, e.g., as illustrated in FIGS. 3A and 3B. The interconnect structure 214 can have a ring shape or disk shape, e.g., as illustrated in FIG. 3A or 3B. As the side connection stack 140 is part of the first stack 106, the contact structure 117 is thus electrically connected to the corresponding conductive layer 136 (e.g., gate layers 136-2 for controlling memory cells) of the first stack 106 in the array region 102, achieving word line pick-up/fan-out.

The interconnect structure 214 can have the same conductive material as the vertical contact 212. In some implementations, the conductive material includes, without limitation to, W, Co, Cu, Al, TiN, TaN, polysilicon, or any combination thereof. The spacer layer 216 and/or the dielectric body structure 218 can include, without limitation to, silicon oxide, silicon nitride, silicon oxynitride, or any combination thereof. In some implementations, vertical contact 212 and interconnect structure 214 include TiN/W, and the spacer layer 216 and the dielectric body structure 218 includes silicon oxide.

FIG. 2C is a cross-section view of the semiconductor device 100 through an axis similar to the axis B-B′ of FIG. 1, which passes through a TSG cut structure 120. It is to be understood that for ease of illustration, the channel structures 110 are not depicted in FIG. 2C.

A TSG cut structure 120 extends horizontally along X direction through the first part 103 of the first portion 202 of the first stack 106. The TSG cut structure 120 includes a first end 242 and a second end 244 opposite to the first end 242 along X direction. In some implementations, the second end 244 of the TSG cut structure 120 is between the first staircase structure 210 and the second staircase structure 220. That is, the TSG cut structure 120 terminates near the midpoint between the first part 103 and the second part 105, as illustrated in FIG. 2C. In some implementations, the second end 244 of the TSG cut structure 120 is between the first staircase structure 210 and the second stack 108. For example, the TSG cut can further extend into the second staircase structure 220 but terminate before reaching the second stack 108. In some implementations, the TSG cut structures 120 have a length shorter than that of the gate layers 136-2 along the X direction.

In some implementations, the TSG cut structure 120 extends vertically (e.g., along Z direction) through the first part 103 of the first portion 202 of the first stack 106 and at least one of the conductive layers (e.g., the gate layers 136-2) that are adjacent to the first portion 202 of the first stack 106. For example, in the present example illustrated in FIG. 2C, the TSG cut structure 120 can cut through five TSG layers 136-1 in the first part 103 of the first portion 202 and about two upper gate layers 136-2 in the second portion 204. The TSG cut structure 120 can separate each of the TSG layers 136-1 into multiple TSG electrodes 121, as illustrated in FIG. 1. Likewise, the TSG cut structures 120 can separate a section of the upper gate layer 136-2 into multiple individual layer portions 310, as illustrated in FIG. 3A. In some implementations, not all the gate layers 136-2 in the second portion 204 are penetrated by the TSG cut structures 120 along Z direction. For example, as illustrated in FIG. 2C, the lower layers of the gate layers 136-2 remain intact without being cut by the TSG cut structure 120. The lower layers of the gate layers 136-2 can be the gate layers that are closer to the substrate 201. The at least one of the conductive layers (e.g., the upper layers of the gate layers 136-2) in the second portion 204 that are penetrated or cut by the TSG cut structure 120 can be referred to as the sliced gate layers in this disclosure.

FIG. 3A illustrate a cross-section view of the semiconductor device 100 along an axis similar to the axis C-C′ of FIG. 2A, which passes through one of example sliced gate layers. It is to be understood that for ease of illustration, the channel structures 110 are not depicted in FIG. 3A. FIG. 3B illustrates a 3D view of a part of the semiconductor device 100 showing example contact structures 117. Reference will be made to both figures when describing contact structures 117.

As noted above, the second end 244 of the TSG cut structure 120 can terminate before reaching the second stack 108 along the X direction, leaving a section of the sliced gate layers 136-2 adjacent to the second stack 108 in its intact state. For example, each sliced gate layer 136-2 can include a first section 302 and a second section 304 arranged laterally along X direction. The first section 302 of the sliced gate layers 136-2 can be the section that is penetrated by the TSG cut structure 120, while the second section 304 of the sliced gate layers 136-2 can be the remaining section that is not affected by the TSG cut structure 120. As illustrated in FIG. 3A, in some implementations, the TSG cut structure 120 separates the first section 302 of the sliced gate layers 136-2 into a plurality of layer portions 310, and the second section 304 of the sliced gate layers 136-2 connects ends 306 of the plurality of layer portions 310. Consequently, the layer portions 310 are interconnected to each other through the second section 304 of the sliced gate layers 136-2. When a voltage potential is applied to any section of the sliced gate layers 136-2, it can propagate throughout the remaining sections of the layers. Therefore, the combined sections of each sliced gate layer can function similarly to a single continuous gate layer. In some implementations, the second part 105 of the sliced gate layers 136-2 is between the TSG cut structure 120 and the second stack 108 along the X direction.

As noted above, the contact structure 117 can include a vertical contact 212 and an interconnect structure 214. The interconnect structure 214 can have a circular shape in a top view, as illustrated in FIGS. 3A and 3B. The interconnect structure 214 can be connected to a corresponding conductive layer 136 in the side connection stack 140. Through the interconnect structure 214 and the side connection stack 140, the sliced gate layer 136-2 can be electrically coupled to the corresponding vertical contact 212. When a voltage potential is applied to the corresponding contact structure 117, each individual layer portion 310 of the sliced gate layer 136-2 can share the same voltage potential through the second section 304 of the sliced gate layer 136-2. Therefore, the memory cells that are controlled by the sliced gate layers 136-2 can still function as active memory cells for data storage, thereby improving storage capacity.

FIGS. 4A-4D illustrates cross-section views of the example semiconductor device 100 of FIG. 2A at various stages of a manufacturing process. As illustrated in FIG. 4A, a stack structure 402 is formed, which has dielectric layers 138 and isolating layers 134 alternating with each other along the first direction, e.g., Z direction. The isolating layer 134 and/or the dielectric layers 138 can be made of dielectric materials including, but not limited to, silicon oxide, silicon nitride, silicon oxynitride, or any combination thereof. In some implementations, the isolating layer 134 includes silicon oxide, and the dielectric layer includes silicon nitride. The isolating layer 134 and the dielectric layers 138 can be formed by one or more thin film deposition processes including, but not limited to, CVD, PVD, ALD, MOCVD, MBE, sputtering, or any combination thereof.

A first portion 202 of the stack structure 402 can be etched to form a first initial staircase 404 in a first part 103 of the first portion 202 and a second initial staircase 406 in a second part 105 of the first portion 202. The opening between the first initial staircase 404 and the second initial staircase 406 can be filled with a dielectric material to form a separation structure 208. The combination of both initial staircases can have a bowl shape, as illustrated in FIG. 4A. The separate structure 208 can have a dielectric material, including, but not limited to, silicon oxide, silicon nitride, silicon oxynitride, or any combination thereof. The etching process for forming initial staircases can involve one or more dry etching and/or wet etching techniques, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof.

Referring to FIG. 1, in some implementations, slit structures 118 are formed extending along the X direction. Slit cuts 122 can also be formed which extends through the slit structure 118 along the Z directions. In some implementations, the slit structures 118 and/or slit cuts 122 are deposited by one or more thin film deposition processes including, but not limited to, chemical vapor deposition (CVD), physical vapor deposition (PVD), atomic layer deposition (ALD), Metal-Organic Chemical Vapor Deposition (MOCVD), sputtering, electroplating, electroless plating, electron-beam evaporation, or any combination thereof.

As illustrated in FIG. 4B, the dielectric layers 138 can be partially replaced with the conductive layers 136 in the stack structure 402 to form the first stack 106. The remaining part of the stack structure 402 can form the second stack 108. This replacement process can involve removing part of the dielectric layers 138 by a wet etch and/or dry etch process. After the partial removal of the dielectric layers 138, a plurality of openings can be formed between adjacent isolating layers 134. A conductive material can be deposited into the openings to form conductive layers 136 (e.g., the gate layers 136-2 and TSG layers 136-1). The conductive layers 136 can be isolated from one another by the isolating layers 134. In some implementations, conductive layers 136 are made of conductive materials including, but not limited to, W, Co, Cu, Al, polysilicon, doped silicon, silicides, or any combination thereof. In some implementations, the conductive material is deposited by one or more thin film deposition processes including, but not limited to, CVD, PVD, ALD, MOCVD, MBE, sputtering, or any combination thereof.

In some implementations, the replacement process for the semiconductor device 100 includes two steps: one for forming the first stack 106 in the array region 102, and the other one for forming the side connection stack 140 in the connection region 104. Referring back to FIG. 1, at the first step, the slit material (e.g., polysilicon) in the first segment 116a of the slit structure 118 can be removed, forming slit trenches in the array region 102. Etchants can be introduced through the slit trenches to remove the dielectric layers 138 and form openings between adjacent isolating layers 134 in the array region 102. The openings can be subsequently filled with the gate layers 136, forming the first stack 106 in the array region 102. At the end of the first step, the slit trenches can be refilled with the slit material (e.g., poly). The second step can be substantially similar to the first step, expect that the process occurs in the connection region 104 and the etching time for removing the dielectric layers 138 can be shorter. For example, the slit material (e.g., polysilicon) in the second segment 116b of the slit structure 118 can be removed, forming slit trenches in the connection region 104. Etchants can be introduced through the slit trenches to remove the dielectric layers 138 and form openings in the edge portions of the connection region 104 (e.g., the region of the side connection stacks 140). The openings in the region of the side connection stacks 140 can be subsequently filled with a conductive material (e.g., W) to form the gate layers 136. The slit trenches can be then refilled with the slit material (e.g., polysilicon). In some implementations, the etching time for removing the dielectric layers 138 in the connection region 104 is shorter than that in the array region 102. Therefore, only edge portion of the connection region 104 are replaced with W, leaving the dielectric layers 138 in the second stack 108 unaffected.

As illustrated in FIG. 4C, at least one TSG cut structure 120 can be formed which extends vertically through the TSG layers 136-1 and at least one of the gate layers 136-2 along the first direction, e.g., Z direction. The TSG cut structure 120 is configured to separate the TSG layers 136-1 into a plurality of TSG electrodes 121. The TSG cut structure 120 includes a first end 242 and a second end 244 opposite to the first end 242 along the X direction. The second end 244 of the TSG cut structure 120 can be between the first staircase structure 210 and the second staircase structure 220, as illustrated in FIG. 4C. In some implementations, the TSG cut structure 120 also extends through the second staircase structure 220 along X direction, but terminates before reaching the second stack 108, such that the length 422 of the TSG cut structure 120 along X direction is smaller than the length 420 of the gate layers 136-2.

As noted above in reference to FIG. 3A, the TSG cut structure 120 can divide the first section 302 of the sliced gate layers 136-2 into multiple layer portions 310. The layer portions 310 of sliced gate layers 136-2 can be connected together through the second section 304 of the sliced gate layer 136-2. The TSG cut structure 120 can be made of dielectric materials including, but not limited to, silicon oxide, silicon nitride, silicon oxynitride, or any combination thereof.

FIG. 4D is identical to FIG. 2A. It is to be understood that FIG. 4C and FIG. 4D can be from different cross-section planes of the example semiconductor device 100. As illustrated in FIG. 4D, a plurality of TSG contact structures 130 can be formed. A TSG contact structure 130 can be in contact with a corresponding one of the TSG electrodes 121 at a corresponding first stair 206. Forming the TSG contact structures 130 can involve forming holes extending through at least one inter-layer dielectric (ILD) layers 414 and depositing a conductive material inside the holes. In some implementations, the inter-layer dielectric (ILD) layers 414 are formed after forming the TSG cut structures 120. The TSG contact structures 130 can be made of a conductive material including, but not limited to W, Co, Cu, Al, TiN, TaN, polysilicon, silicide, or any combination thereof. In some implementations, the TSG contact structures 130 includes multiple conductive layers 136, such as a W layer over a TiN layer.

The contact structures 117 can be formed which extend into the second stack 108 at different depths. A contact structure 117 is coupled to a corresponding one of the conductive layers 136, e.g., as illustrated in FIGS. 3A and 3B. A contact structure 117 can include a vertical contact 212 and an interconnect structure 214. The interconnect structure 214 can be formed by replacing a portion of the corresponding dielectric layer with a conductive material. In some implementations, a diameter of the interconnect structure 214 is greater than an outer diameter of the conductive layer 222 of the vertical contact 212 in a cross-section plane parallel to the substrate surface (e.g., the X-Y plane). In some implementations, the interconnect structure 214 is in contact with a corresponding conductive layer 136 in the side connection stack 140 located in the connection region 104, as illustrated in FIGS. 3A and 3B.

The interconnect structure 214 can have the same conductive material as the vertical contact 212. In some implementations, the conductive material includes, without limitation to, W, Co, Cu, Al, TiN, TaN, polysilicon, or any combination thereof. The spacer layer 216 includes, without limitation to, silicon oxide, silicon nitride, silicon oxynitride, or any combination thereof. In some implementations, vertical contact 212 and interconnect structure 214 include TiN/W, and the spacer layer 216 includes silicon oxide.

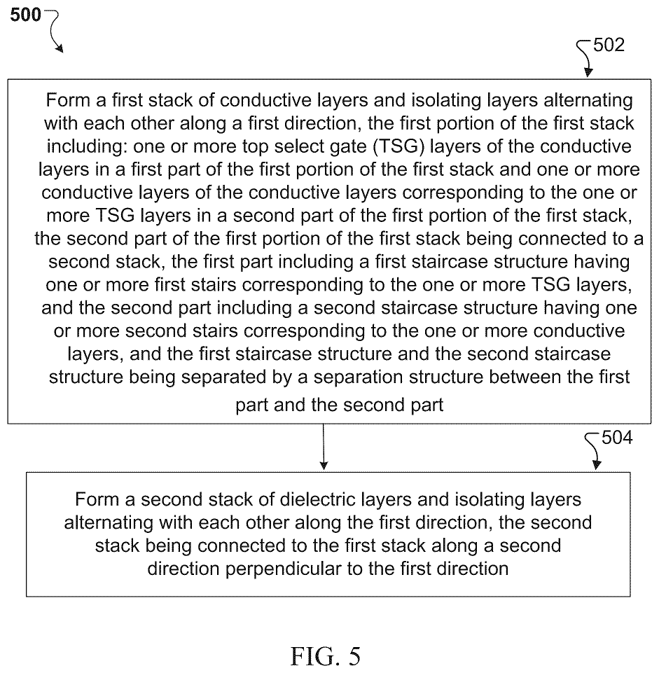

FIG. 5 illustrates a flow chart of an example process 500 for forming the example semiconductor device 100. At step 502, a first stack is formed. The first stack has conductive layers and isolating layers alternating with each other along a first direction. The first portion of the first stack includes: one or more top select gate (TSG) layers of the conductive layers in a first part of the first portion of the first stack and one or more conductive layers of the conductive layers corresponding to the one or more TSG layers in a second part of the first portion of the first stack. The second part of the first portion of the first stack is connected to a second stack. The first part includes a first staircase structure having one or more first stairs corresponding to the one or more TSG layers. The second part includes a second staircase structure having one or more second stairs corresponding to the one or more conductive layers. The first staircase structure and the second staircase structure are separated by a separation structure between the first part and the second part. The first stack can be, e.g., the first stack 106 of FIGS. 1, 2A, 2C-3A, and 4B-4D. The first portion of the first stack can be, e.g., the first portion 202 of FIGS. 2A, 2C and 4A-4D. The second portion of the first stack can be, e.g., the second portion 204 of FIGS. 2A, 2C and 4A-4D. The first part of the first portion of the first stack can be, e.g., the first part 103 of FIGS. 1, 2A, 2C and 4A-4D. The second part of the first portion of the first stack can be, e.g., the second part 105 of FIGS. 1, 2A, 2C and 4A-4D. The conductive layers can be, e.g., the conductive layers 136 of FIGS. 2A, 2C, 3A, 3B and 4B-4D. The TSG layers can be, e.g., the TSG layers 136-1 of FIGS. 2A and 4B-4D. The first staircase structure can be, e.g., the first staircase structure 210 of FIGS. 1-2B and 4B-4D. The second staircase structure can be, e.g., the second staircase structure 220 of FIGS. 1-2B and 4B-4D. The first stairs can be, e.g., the first stairs 206 of FIGS. 2A, 2B and 4B-4D. The second stairs can be, e.g., the second stairs 207 of FIGS. 2A-2C and 4B-4D. The separation structure can be, e.g., the separation structure 208 of FIGS. 2A-2C and 4A-4D. The first direction can be the direction perpendicular to the top substrate surface, e.g., the Z direction.

At step 504, a second stack is formed. The second stack includes dielectric layers and isolating layers alternating with each other along the first direction. The second stack is connected to the first stack along a second direction perpendicular to the first direction. The second stack can be, e.g., the second stack 108 of FIGS. 1, 2A, 2C-4D. The dielectric layers can be, e.g., the dielectric layers 138 of FIGS. 2A, 2C and 3A-4D. The second direction can be a lateral direction parallel to the substrate surface or a word line direction, e.g., X direction.

In some implementations, a stack structure of the dielectric layers and the isolating layers alternating with each other along the first direction is formed. A first portion of the stack structure is etched to form a first initial staircase in a first part of the first portion and a second initial staircase in a second part of the first portion. The stack structure can be, e.g., the stack structure 402 of FIG. 4A. The first initial staircase can be, e.g., the first initial staircase 404 of FIG. 4A. The second initial staircase can be, e.g., the second initial staircase 406 of FIG. 4A.

In some implementations, the dielectric layers are partially replaced with the conductive layers in the stack structure to form the first stack, as illustrated in FIG. 4B.

In some implementations, a TSG cut structure is formed, extending through the TSG layers and at least one of the conductive layers along the first direction. The TSG cut structure is configured to separate the TSG layers into a plurality of TSG electrodes. The TSG cut structures can be, e.g., the TSG cut structures 120 of FIGS. 1, 2C, 3A and 4C. The TSG electrodes can be, e.g., the TSG electrodes 121 of FIG. 1.

In some implementations, the TSG cut structure includes a first end and a second end opposite to the first end along the second direction. The second end of the TSG cut structure is between the first staircase structure and the second staircase structure. The first end can be, e.g., the first end 242 of FIGS. 1, 2C, 3A and 4C. The second end can be, e.g., the second end 244 of FIGS. 1, 2C, 3A and 4C.

In some implementations, a slit structure is formed extending along the second direction. A slit cut is formed extending through the slit structure along the first direction. The slit cut separates the slit structure into a first segment and a second segment, and the slit cut is between the first staircase structure and the second stack. The slit structure can be, e.g., the slit structure 118 of FIGS. 1 and 3B. The slit cut can be, e.g., the slit cut 122 of FIG. 1. The first segment can be, e.g., the first segment 116a of FIG. 1. The second segment can be, e.g., the second segment 116b of FIG. 1.

In some implementations, a plurality of TSG contact structures is formed. One of the TSG contact structures is in contact with a corresponding one of the TSG electrodes at a corresponding one of the one or more first stairs. The TSG contact structures can be, e.g., the TSG contact structures 130 of FIGS. 1, 2A and 4D.

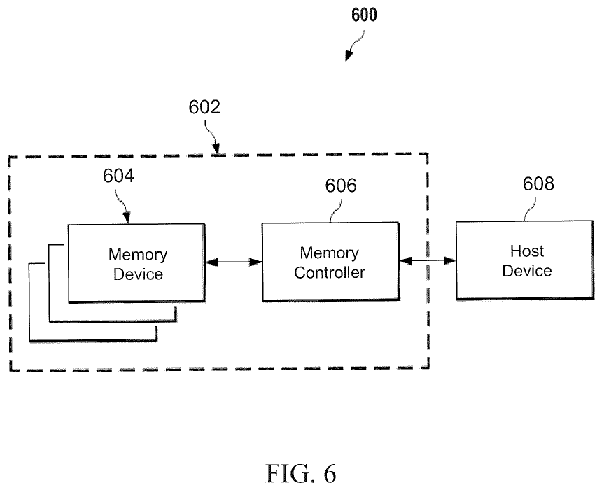

FIG. 6 illustrates a block diagram of a system 600 having one or more semiconductor device 100s (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as the 3D semiconductor device 100 of FIGS. 1, 2A, 2C and 4D, or a part of the 3D semiconductor device 100 of FIGS. 2B, 3A and 3B, or a structure at an intermediate fabrication process of the 3D semiconductor device 100 of FIGS. 4A-4C.

In some implementations, a 3D memory device 604 includes a NAND Flash memory. Memory controller 606 (a.k.a., a controller circuit) is coupled to 3D memory device 604 and host device 608. Consistent with implementations of the present disclosure, 3D memory device 604 can include a plurality of conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 may be configured to operate a plurality of channel structures via word lines. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” “one implementation,” “an implementation,” “an example implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect structures, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−. 20%, or .+−. 30% of the value).

As used in this disclosure, the term “substantially” or “substantial” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first stack of conductive layers and isolating layers alternating with each other along a first direction; and
a second stack of dielectric layers and isolating layers alternating with each other along the first direction, wherein the second stack is connected to the first stack along a second direction perpendicular to the first direction,
wherein a first portion of the first stack comprises:
one or more top select gate (TSG) layers of the conductive layers in a first part of the first portion of the first stack,
one or more conductive layers of the conductive layers corresponding to the one or more TSG layers in a second part of the first portion of the first stack, the second part of the first portion of the first stack being connected to the second stack,
wherein the first part comprises a first staircase structure having one or more first stairs corresponding to the one or more TSG layers, and the second part comprises a second staircase structure having one or more second stairs corresponding to the one or more conductive layers, and
wherein the first staircase structure and the second staircase structure are separated by a separation structure between the first part and the second part.

2. The semiconductor device of claim 1, wherein a number of the one or more first stairs is equal to a number of the one or more second stairs.

3. The semiconductor device of claim 1, further comprising:
a TSG cut structure extending through the first part of the first portion of the first stack and at least one of the conductive layers in a second portion of the first stack that is adjacent to the first portion of the first stack along the first direction, the TSG cut structure configured to separate the one or more TSG layers into a plurality of TSG electrodes.

4. The semiconductor device of claim 3, wherein a conductive layer of the at least one of the conductive layers comprises a first section and a second section, and
wherein the TSG cut structure is configured to separate the first section of the conductive layer into a plurality of layer portions, and the second section of the conductive layer connects ends of the plurality of layer portions.

5. The semiconductor device of claim 4, wherein the second section of the conductive layer is between the TSG cut structure and the second stack along the second direction.

6. The semiconductor device of claim 3, wherein the TSG cut structure comprises a first end and a second end opposite to the first end along the second direction, and wherein the second end of the TSG cut structure is between the first staircase structure and the second stack.

7. The semiconductor device of claim 6, wherein the second end of the TSG cut structure is between the first staircase structure and the second staircase structure.

8. The semiconductor device of claim 3, further comprising TSG contact structures, one of the TSG contact structures being in contact with a corresponding one of the plurality of TSG electrodes at a corresponding one of the one or more first stairs along the first direction.

9. The semiconductor device of claim 1, further comprising a slit structure extending along the second direction and comprising a first portion and a second portion, the first portion and the second portion of the slit structure being separated by a slit cut.

10. The semiconductor device of claim 9, wherein the slit cut is between the first part of the first portion of the first stack and the second stack along the second direction.

11. The semiconductor device of claim 1, further comprising a plurality of contact structures, wherein the plurality of contact structures extends into the second stack at different depths, and wherein one of the plurality of contact structures comprises a vertical contact and an interconnect structure connected with the vertical contact.

12. A method, comprising:
forming a first stack of conductive layers and isolating layers alternating with each other along a first direction; and
forming a second stack of dielectric layers and isolating layers alternating with each other along the first direction, wherein the second stack is connected to the first stack along a second direction perpendicular to the first direction,
wherein a first portion of the first stack comprises:
one or more top select gate (TSG) layers of the conductive layers in a first part of the first portion of the first stack,
one or more conductive layers of the conductive layers corresponding to the one or more TSG layers in a second part of the first portion of the first stack, the second part of the first portion of the first stack being connected to the second stack,
wherein the first part comprises a first staircase structure having one or more first stairs corresponding to the one or more TSG layers, and the second part comprises a second staircase structure having one or more second stairs corresponding to the one or more conductive layers, and
wherein the first staircase structure and the second staircase structure are separated by a separation structure between the first part and the second part.

13. The method of claim 12, comprising:
forming a stack structure of the dielectric layers and the isolating layers alternating with each other along the first direction; and
etching a first portion of the stack structure to form a first initial staircase in a first part of the first portion and a second initial staircase in a second part of the first portion.

14. The method of claim 13, comprising: partially replacing the dielectric layers with the conductive layers in the stack structure to form the first stack.

15. The method of claim 12, comprising: forming a TSG cut structure extending through the TSG layers and at least one of the conductive layers along the first direction, wherein the TSG cut structure is configured to separate the TSG layers into a plurality of TSG electrodes.

16. The method of claim 15, wherein the TSG cut structure comprises a first end and a second end opposite to the first end along the second direction, and wherein the second end of the TSG cut structure is between the first staircase structure and the second staircase structure.

17. The method of claim 12, comprising:
forming a slit structure extending along the second direction; and
forming a slit cut extending through the slit structure along the first direction, wherein the slit cut separates the slit structure into a first segment and a second segment, and the slit cut is between the first staircase structure and the second stack.

18. The method of claim 15, comprising:
forming a plurality of TSG contact structures, one of the TSG contact structures being in contact with a corresponding one of the TSG electrodes at a corresponding one of the one or more first stairs.

19. A semiconductor device, comprising:
a first stack of conductive layers and isolating layers alternating with each other along a first direction, wherein a first portion of the first stack comprises one or more top select gate (TSG) layers of the conductive layers;
a second stack of dielectric layers and isolating layers alternating with each other along the first direction, wherein the second stack is connected to the first stack along a second direction perpendicular to the first direction; and
a TSG cut structure extending through the first portion of the first stack and at least one of the conductive layers in a second portion of the first stack that is adjacent to the first portion of the first stack along the first direction, the TSG cut structure being configured to separate the one or more TSG layers into a plurality of TSG electrodes,
wherein a conductive layer of the at least one of the conductive layers comprises a first part and a second part, and the second part is between the first part and the second stack, and
wherein the TSG cut structure is configured to separate the first part of the conductive layer into a plurality of layer portions, and the second part connects ends of the plurality of layer portions.

20. The semiconductor device of claim 19, wherein the first portion comprises a first staircase structure having one or more first stairs corresponding to the one or more TSG layers, and the semiconductor device further comprises TSG contact structures, one of the TSG contact structures being in contact with a corresponding one of the plurality of TSG electrodes at a corresponding one of the first stairs.
